(19) United States
(12) Patent Application Publication
(10) Pub. No.: US 2012/0115332 A1
(43) Pub. Date: May 10, 2012

(54) Method of Post Etch Polymer Residue Removal

(75) Inventors: Seokmin Yun, Pleasanton, CA (US); Mark Wilcoxson, Oakland, CA (US); Ji Zhu, El Cerrito, CA (US); Kevin Chuang, Jhubei City (TW); Hsiao Wei Chang, Fremont, CA (US); David Lou, Jhubei City (TW)

(73) Assignee: LAM RESEARCH CORPORATION, Fremont, CA (US)

(21) Appl. No.: 13/354,322

(22) Filed: Jan. 19, 2012

Related U.S. Application Data
(62) Division of application No. 11/827,479, filed on Jul. 11, 2007.

(51) Int. Cl. H01L 21/3065

(52) U.S. Cl. 438/716; 257/E21.218

(57) ABSTRACT

A method for processing a substrate includes etching a surface of the substrate using an etching chemistry in a plasma chamber, the etching configured to define one or more features on the surface of the substrate. The features have some etch polymer residues as a result of the etching. The etching is terminated. A dry flash chemistry is applied into the plasma chamber. The plasma chamber is powered for a period of time between about 5 seconds and about 10 seconds to perform a dry flash etch. During the dry flash etch, the chamber is set to a low pressure of between about 5 mTorr and about 40 mTorr. The dry flash etch acts to weaken adhesion of the etch polymer residues to the features. The substrate is moved from plasma chamber and into a wet clean chamber for cleaning which removes the etch polymer residues during fluid cleaning.

### CLAIM OF PRIORITY

This application is a divisional application of U.S. application Ser. No. 11/827,479 entitled “Method of Post Etch Polymer Residue Removal” filed on Jul. 11, 2007 and incorporated herein by reference.

### FIELD OF THE INVENTION

The present invention relates generally to semiconductor substrate processing, and more particularly, to an improved technique for removing post etch polymer residues from substrate surfaces by careful process optimization of dry and wet processes.

### DESCRIPTION OF THE RELATED ART

As the technological advancement proceeds into the deep sub-micron regime, the number of devices in an integrated circuit (IC) chip reaches into the tens of millions. This progression in miniaturization of semiconductor devices has brought with it a succession of technological complexities. For one, the electrical resistance and parasitic capacitance associated with metal interconnects has started to significantly contribute to the circuit speed of the IC. To improve the performance of the ICs, the semiconductor industry has transitioned from aluminum metal to copper metal for interconnects and to the use of low-k dielectric material instead of the silicon dioxide between the metal interconnect lines. Copper reduces the electrical resistance as it is a better conductor and is more electromigration resistant than aluminum. Usage of copper metal for interconnects also enables smaller and thinner conductive lines so that more devices can be packed on individual chips. The low-k dielectric material reduces the parasitic capacitance between the metal lines thereby increasing the performance of the IC chips.

Copper interconnects are fabricated using a process known as dual damascene. The dual damascene fabrication process is the most popular and widely implemented dielectric etch approach today. Damascene refers to the process by which a metal conductor pattern is embedded within a non-conducting (dielectric) material, then metal is deposited to fill resulting trenches and finally excess metal is removed by means of chemical-mechanical polishing. In dual damascene the process sequentially creates embedded vias and trenches, with the vias forming the vertical connections from one layer of circuitry (trenches) to the next. The damascene etch process for vias and trenches require mixtures of fluorocarbon, hydrofluorocarbon, oxygen and nitrogen gases. These etching mixtures can leave polymer residues on the dielectric sidewall and bottom of the etched structures. The etching operation using dual damascene process can be implemented using different schemes, such as photoresist (PR) mask scheme or a hard mask scheme.

In the PR mask scheme, an etch stop layer is deposited to allow for self-alignment of underlying contacts with the interconnects while maintaining the structural integrity of the feature. A PR mask is then used to etch the dielectric film layer, after which the PR layer and the etch stop layer are then stripped. The stripping chemicals used in stripping the PR layer and the etch stop layer can potentially damage the low-k dielectric film layer. Additionally, the polymer residues from the etch chemicals used in the PR mask scheme deposit along the walls of the narrow trenches and vias making it difficult to remove the residues.

In the hard mask scheme, a dielectric or metal hard mask is used instead of PR mask. Etching is performed with the hard mask. Since hard mask is used in this scheme, the operation of stripping the PR mask is avoided thereby minimizing the damage caused by the PR stripping process. However, the hard mask needs to be carefully removed so as to minimize the damage to the underlying dielectric film layer and to the structures formed therein.

Conventionally, post-etch residues have been removed by wet chemical processes using wet cleaning chemicals. These wet chemicals are adept at removing residues having metallic components, such as copper oxides of different oxidation states. However, carbon containing organic residues in the narrow vias and trenches pose a significant challenge as it is very difficult to remove these residues without damaging the etched dielectric structures. Further, the wet chemicals alone are not very effective in substantially removing these organic residues.

In view of the foregoing, there is a need for a more effective method for removing post-etch polymer residues without damaging the etched structures and the surrounding dielectric materials. There is also a need to reduce the complexity of the chemistry being used so as to reduce the cost of cleaning while providing a more effective cleaning. There is also a need to provide an alternative solution which can clean the surface of the substrate under benign conditions.

### SUMMARY

The present invention fills the need by providing an improved method and apparatus for removing post-etch polymer residue from the surface of the substrate. It should be appreciated that the present invention can be implemented in numerous ways, including as an apparatus and a method. Several inventive embodiments of the present invention are described below.

In one embodiment, a method for processing a substrate is disclosed. The method comprises etching a surface of the substrate using an etching chemistry in a plasma chamber. The etching is configured to define one or more features on the surface of the substrate. The one or more features include at least some etch polymer residues as a result of the etching. The etching with the etching chemistry is terminated. After terminating the etching, a dry flash chemistry is applied into the plasma chamber. The plasma chamber is then powered for a period of time of between about 5 seconds and about 10 seconds to perform a dry flash etch. During the dry flash etch, the plasma chamber is set to a low pressure of between about 5 mTorr and about 40 mTorr. The dry flash etch acts to weaken adhesion of the etch polymer residues to the one or more features. The substrate is moved from the plasma chamber and into a wet clean chamber for fluid cleaning. The fluid cleaning is applied over the etch polymer residues that have weakened adhesion such that the etch polymer residues are removed during the fluid cleaning.

Other aspects and advantages of the invention will become more apparent from the following detailed description, taken in conjunction with the accompanying drawings, illustrating by way of example the present invention.

### BRIEF DESCRIPTION OF THE DRAWINGS

The invention may best be understood by reference to the following description taken in conjunction with the accompanying drawings. These drawings should not be taken to limit the invention to the preferred embodiments, but are for explanation and understanding only.

FIG. 1 illustrates a cross-section of a polymer residue formed in and around a feature formed in a low-k dielectric film layer.

FIG. 2A illustrates a cross-section view of a system used in applying dry flash and wet chemistry, in one embodiment of the invention.

FIG. 2B illustrates an alternate embodiment of a system illustrated in FIG. 2A, in another embodiment of the invention.

FIG. 3 illustrates a flow chart of the operations involved in applying dry flash and wet chemistry to effectively remove post-etch polymer residue, in one embodiment of the invention.

### DETAILED DESCRIPTION

Several embodiments for effectively removing post-etch polymer residue from around features formed in a low-k dielectric film layer of a substrate, will now be described. It will be obvious, however, to one skilled in the art, that the present invention may be practiced without some or all of these specific details. In other instances, well known process operations have not been described in detail in order not to unnecessarily obscure the present invention.

The post-etch polymer residues of organic components, left behind by an etching operation such as a dual damascene etching process, have posed a real challenge in the semiconductor fabrication process as these polymer residues are difficult to remove. Conventional cleaning operations using wet cleaning chemistries alone have not been very effective in substantially removing these polymer residues. Moreover, with the conventional cleaning operations, the surface of the substrate has to be exposed to the wet cleaning chemistries for a prolonged period of time in order for these wet cleaning chemistries to act on the polymer residue and release these residues from the surface of the substrate. The prolonged exposure to these wet cleaning chemistries may result in the damage of the dielectric film layers and the underlying structures and features, such as copper contacts. In order to effectively remove the polymer residue while preserving the characteristics of the dielectric film layer and the underlying structures, the surface of the substrate is carefully treated with a combination of a dry and a wet cleaning chemistry.

Careful treatment of the surface of the substrate with dry and wet cleaning chemistry enables effective removal of the organic polymer residues from the surface while preserving the quality of the features formed on the substrate and the resulting semiconductor products, e.g., microchips. In an embodiment of the invention, a dry flash chemistry for removing the post-etch polymer residue, is identified. The dry flash chemistry is chosen such that the dry flash chemistry is able to remove at least a portion of the post-etch polymer residue from the surface of the substrate. The identified dry flash chemistry is to effectively remove the post-etch polymer residue from the surface of the substrate 100. The flash process is optimized so as to minimize the damage to the surrounding low-k dielectric film layer and the underlying structures, usually by limiting the time of application to be short. The short flash process using the dry flash chemistry is followed by a wet cleaning operation wherein a wet cleaning chemistry is identified and applied to the surface of the substrate so that the remainder of the polymer residue left behind by the short flash process is substantially removed. As in the flash process, the application of the wet cleaning chemistry is optimized so that the damage to the surrounding dielectric film layer is minimized. Advantages of using a combination of dry and wet cleaning chemistries are numerous. For instance, the short flash process, using dry flash chemistry, enables using less complex and, hence, less expensive wet cleaning chemistry to effectively remove the organic polymer residues from the surface of the substrate. Further, the application time for the wet cleaning chemistry is greatly reduced as substantial portions of the polymer residue have already been removed by the short flash process. Less application time of the wet cleaning chemistry to the surface of the substrate results in less damage to the low-k dielectric film layer and higher throughput.

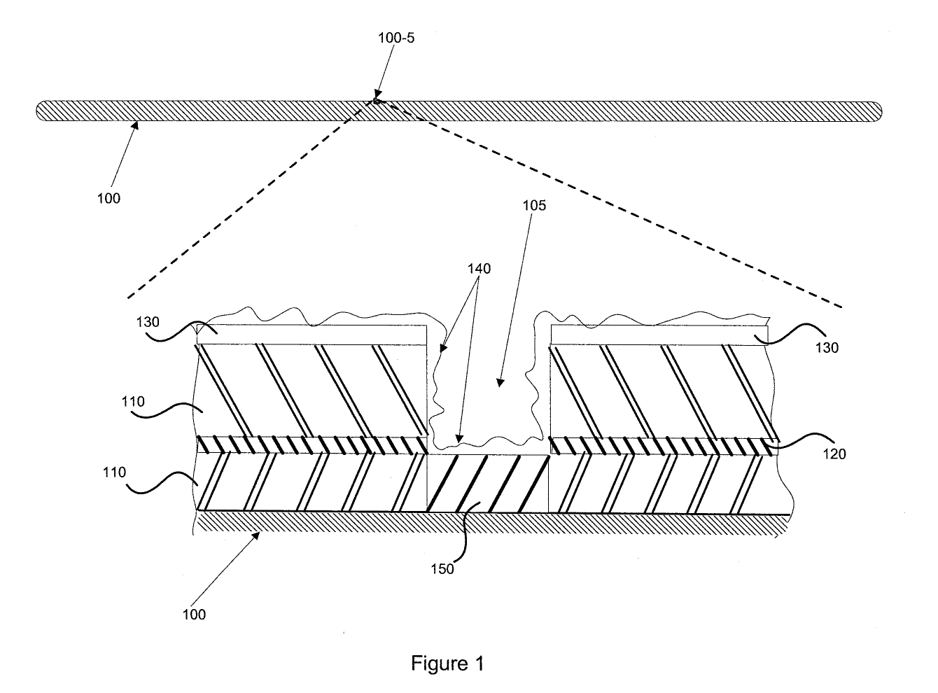

FIG. 1 illustrates a simplified schematic diagram of a portion 100-5 of a substrate 100 wherein a polymer residue is formed along the walls and the bottom of a feature etched in a low-k dielectric film layer. As shown, the portion 100-5 of the substrate 100 includes a low-k dielectric film layer 110 formed on the substrate 100. The low-k dielectric film layer 110 is formed using any one of spin coating, dip coating, or by a chemical vapor deposition technique. The material used in forming the low-k dielectric film layer 110 can be one of SiCOH, porous SiCOH, etc. The low-k dielectric material is doped with carbon and a plurality of sub-micron pores are introduced into the low-k dielectric material to further lower the dielectric constant. Pores may be introduced using well-known techniques and is, therefore, not discussed in great detail in this application. The low-k dielectric film layer 110 maybe formed directly over a substrate surface, over previously fabricated layers such as etch stop layer or in-between a plurality of fabricated layers. The low-k dielectric film layer 110 provides insulation to one or more features formed through the low-k dielectric film layer 110 or to the underlying structures such as copper interconnects 150 that connect down to transistors formed on the substrate 100. Isolating the features formed on the substrate using low-k dielectric film layer helps in reducing coupling capacitance between features thereby reducing line delay. An etch stop layer 120 is formed on the low-k dielectric film layer 110 to allow for self-alignment of underlying contacts with the copper interconnects 150 and to maintain structural integrity of a feature being formed. A feature 105 is etched in the low-k dielectric film using a dual damascene process. A hard-mask layer or cap layer 130 is formed on top of the etched feature to protect the underlying features from any profile distortion. During the stripping operations, the chemicals used in stripping the etch stop layer 120 and the hard mask layer/cap layer 130 cause polymer residues 140 to deposit in the vias and trenches formed during the dual damascene process. It is, therefore, essential to remove these polymer residues 140 so that the functionality of the features 105 and the characteristics of the low-k dielectric film layer 110 are preserved.

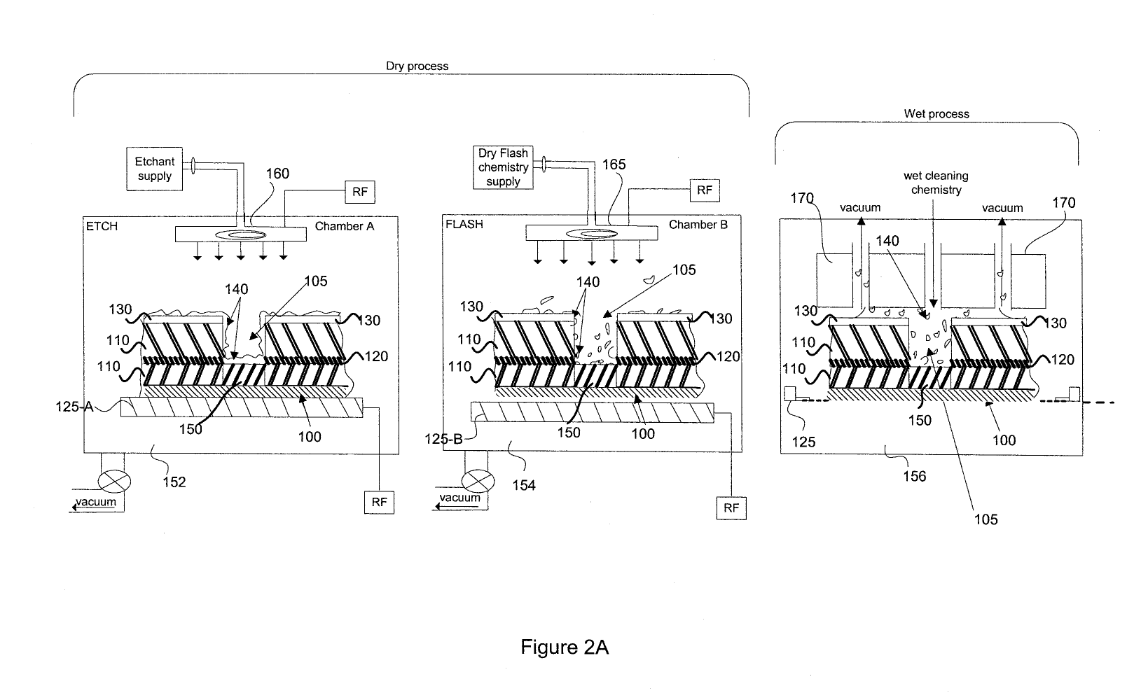

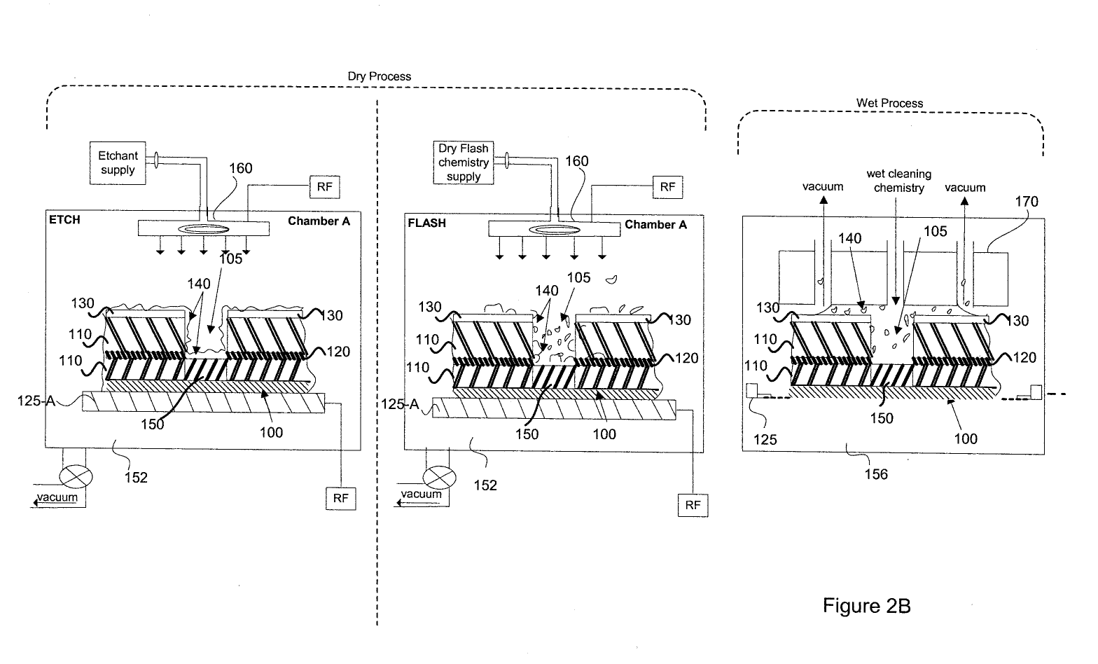

FIG. 2A illustrates a system that is used in removing the polymer residue using a dry flash chemistry, in one embodiment of the invention. The embodiment in FIG. 2A illustrates an exemplary plasma etching reactor chamber having a radio frequency (RF) source and either transformer coupled plasma (TCP) or capacitive coupled plasma. The embodiments of the invention are not restricted to a RF plasma etching reactor but can employ any other conventional etching system. A substrate 100, is received into the first ambient controlled plasma etching reactor chamber (first housing chamber) 152 through an inlet port (not shown). FIG. 2A illustrates only a portion 100-5 of the substrate 100 as being received into the ambient controlled chambers. This is only to exemplify how the dry flash chemistry assists in the removal of the polymer residue during a cleaning operation. The substrate 100 is received into the first housing chamber 152 and disposed on a substrate supporting device, such as a chuck 125-A. The chuck 125-A is powered by a radio frequency generator (RF) coupled to a matching network (not shown) to receive and hold the substrate 100 along a plane so that the substrate 100 is substantially exposed to one or more chemistries applied in the first housing chamber 152. Although the embodiments of the invention have been described using a chuck 125-A to receive and hold the surface of the substrate 100, other types of substrate holding devices may be used.

In the embodiment shown in FIG. 2A, an etchant is introduced into the first housing chamber 152 through a shower head 160 which includes a plurality of holes for releasing gaseous etchant into a RF-induced plasma region between the shower head 160 and the surface of the substrate 100 within the first housing chamber 152. The shower head 160 is connected to a reservoir that is configured to hold and supply etchant chemistry to the first housing chamber 152. A radio frequency (RF) generator is coupled to the shower head 160 through a matching network (not shown) and energizes the shower head. The etchant chemistry is used to etch one or more features on the surface of the substrate 100 using a dual damascene process. The plasma etching reactor chamber is well known in the industry and is, therefore, not described in detail.

The etchant may be introduced into the first housing chamber 152 in a controlled manner using an etchant inlet control. The etchant used in etching features 105 on the substrate 100 usually contain mixtures of fluorocarbons, hydro-fluorocarbons, oxygen and nitrogen gases that may leave polymer residues on the dielectric sidewall and bottom of the etched structure or feature 105. During the stripping operation where the etch stop layer is stripped, residues from the stripping chemical may also be deposited as polymer residue along the walls and bottom of the feature 105 formed in the low-k dielectric film layer 110 of the substrate 100. The first housing chamber 152 includes an outlet that is operatively connected to a vacuum port to collect and remove the etchant and stripping chemical after the etching and stripping operations are performed. The substrate 100 is moved from the first housing chamber 152 to a second housing chamber 154 after the etching and stripping operations so that the polymer residue deposited in and around the features 105 may be cleaned.

A flash chemistry applicator disposed within the second housing chamber 154 introduces a dry flash chemistry into the second housing chamber 154 using a short flash process. A short flash process, as used in this application, is defined as a chemical treatment wherein the dry flash chemistry is applied to the surface of a substrate 100 in a sudden short burst that lasts for a very brief period of time. In one embodiment, the brief period of time may last for about 5 to 7 seconds. As described with reference to the first housing chamber 152, the substrate 100 is received and disposed on a chuck 125-B within the second housing chamber 154. A RF generator connected to the chuck 125-B energizes the chuck 125-B in the second housing chamber 154. The surface of the substrate 100 is treated to the short flash process in the second housing chamber 154. The dry flash chemistry is selected based on the type of polymer residue deposited on the surface of the substrate. One or more parameters associated with the polymer residue are analyzed and the appropriate dry flash chemistry is chosen based on the analysis. In the embodiment of the invention illustrated in FIG. 2A, the flash chemistry applicator is a shower head 165 disposed in the second housing chamber 154. The shower head 165 is similar in structure to the shower head 160 in the first housing chamber 152 and includes a plurality of holes for releasing dry flash chemistry into a RF-induced plasma region within the second housing chamber 152 between the shower head 165 and the surface of the substrate 100. A RF generator is coupled to the shower head 165 through a matching network (not shown) and energizes the shower head 165. As mentioned in relation to etchant, the shower head 165 is connected to a reservoir that receives and supplies the dry flash chemistry to the second housing chamber 154 through the shower head 165. For effective removal of organic polymer residue, the dry flash chemistry includes low-pressure gas such as carbon-dioxide, oxygen, ammonia, nitrogen, hydrogen, methane, carbon monoxide, argon or any combinations of these low-pressure gases.

The exposure of the dry flash chemistry is isotropic (uniform in all directions) in nature which enables uniform application of the dry flash chemistry to a portion of the surface of the substrate 100 so that the polymer residues exposed to the dry flash chemistry are substantially removed.

The flash chemistry applicator includes controls to control the flow of the dry flash chemistry into the second housing chamber 154 so that the dry flash chemistry is applied to the surface of the substrate 100 in a controlled manner. Substantial portions of the polymer residue adhering to the walls of the dielectric film layer and the bottom of the feature are easily stripped by the dry flash chemistry during the short flash process. The stripped polymer residue is promptly removed along with the dry flash chemistry through an outlet operatively connected to a vacuum port. The flash process is kept short as prolonged exposure to the dry flash chemistry significantly damages the dielectric walls and the underlying features. This damage may be attributed to the fact that carbon atoms present in the low-k dielectric film layer 110 can react with free radicals in the plasma. After treatment of the substrate 100 to the short flash process, the substrate 100 is delivered to a third housing chamber 156 through an entry port (not shown) in the third housing chamber 156.

The substrate 100 is received through an inlet port (not shown) in the third housing chamber 156 on a substrate supporting device, such as a carrier 125. The carrier 125 includes pins/rollers to receive and hold the substrate 100 along a plane and motors to transport the substrate along an axis of movement through the third housing chamber 156 and to deliver the substrate through an exit port (not shown) of the third housing chamber 156. The carrier 125 is also configured to rotate the substrate 100 along an axis of rotation so that the substrate 100 is substantially exposed to the wet cleaning chemistry applied in the third housing chamber 156. The carrier 125 includes an inset to receive and hold the substrate 100 in place while being transported through the third housing chamber 156. Although the embodiments of the invention have been described using a carrier 125 to receive and hold the surface of the substrate 100 using pins/rollers, other types of substrate holding devices may be used.

The third housing chamber 156 includes a wet cleaning applicator 170 to introduce a wet cleaning chemistry to the surface of the substrate 100 as the substrate 100 is transported through the third housing chamber 156. The wet cleaning chemistry is selected based on the type of polymer residue deposited on the surface of the substrate 100 and the dry flash chemistry used. Accordingly, one or more parameters associated with the polymer residue and the dry flash chemistry are analyzed and the wet cleaning chemistry is selected based on the analysis.

In an embodiment of the invention, the wet cleaning applicator 170 used in applying the wet cleaning chemistry is a proximity head disposed within the third housing chamber 156 and the wet cleaning chemistry is applied as a liquid meniscus. The term, “meniscus,” as used herein with reference to liquid chemistry, refers to a volume of liquid chemistry bounded and contained in part by surface tension of the liquid chemistry between the opposing surface of a proximity head and a surface of the substrate 100. The meniscus, thus formed, is also controllable and can be moved over a surface in the contained shape and is used to remove the contaminants from the surface of the substrate 100. In specific embodiments, the meniscus shape can be controlled by precision liquid chemistry delivery and removal systems that may further include a computing system.

For more information on the formation of a meniscus and the application to the surface of a substrate, reference may be made to: (1) U.S. Pat. No. 6,616,772, issued on Sep. 9, 2003 and entitled “METHODS FOR WAFER PROXIMITY CLEANING AND DRYING,”; (2) U.S. patent application Ser. No. 10/330,843, filed on Dec. 24, 2002 and entitled “MENISCUS, VACUUM, IPA VAPOR, DRYING MANIFOLD,” (3) U.S. Pat. No. 6,988,327, issued on Jan. 24, 2005 and entitled “METHODS AND SYSTEMS FOR PROCESSING A SUBSTRATE USING A DYNAMIC LIQUID MENISCUS,” (4) U.S. Pat. No. 6,988,326, issued on Jan. 24, 2005 and entitled “PHOBIC BARRIER MENISCUS SEPARATION AND CONTAINMENT,” and (5) U.S. Pat. No. 6,488,040, issued on Dec. 3, 2002 and entitled “CAPILLARY PROXIMITY HEADS FOR SINGLE WAFER CLEANING AND DRYING,” each is assigned to Lam Research Corporation, the assignee of the subject application, and each is incorporated herein by reference. For additional information about top and bottom menisci, reference can be made to the exemplary meniscus, as disclosed in U.S. patent application Ser. No. 10/330,843, filed on Dec. 24, 2002 and entitled “MENISCUS, VACUUM, IPA VAPOR, DRYING MANIFOLD.” This U.S. patent application, which is assigned to Lam Research Corporation, the assignee of the subject application, is incorporated herein by reference.

As described herein, a proximity head is a substrate treatment apparatus that can deliver precise volume of a chemistry to a surface of a substrate 100 to be treated, and remove the chemistry from the surface, when the proximity head is placed in close relation to the surface of the substrate 100. In one example, the proximity head has an opposing head surface (opposing surface) and the opposing surface is placed substantially parallel to the surface of the substrate 100. A meniscus is formed between the opposing surface and the surface of the substrate 100. The proximity head may also be configured to deliver a plurality of chemistry and is equipped with vacuum ports for removing the plurality of chemistry that were delivered.

By controlling the delivery and removal of the chemistry to the meniscus, the meniscus can be controlled and moved over the surface of the substrate 100. In some embodiments, the substrate 100 can be moved, while the proximity head is still, and in other embodiments, the proximity head moves and the substrate 100 remains still, during the processing period. Further, for completeness, it should be understood that the processing can occur in any orientation, and as such, the meniscus can be applied to surfaces that are not horizontal (e.g., vertical substrates or substrates that are held at an angle).

For additional information with respect to the proximity head, reference can be made to an exemplary proximity head, as described in the U.S. Pat. No. 6,616,772, issued on Sep. 9, 2003 and entitled “METHODS FOR WAFER PROXIMITY CLEANING AND DRYING.” This U.S. patent application, which is assigned to Lam Research Corporation, the assignee of the subject application, is incorporated herein by reference. For additional information about the proximity vapor clean and dry system, reference can be made to an exemplary system described in the U.S. Pat. No. 6,488,040, issued on Dec. 3, 2002 and entitled “CAPILLARY PROXIMITY HEADS FOR SINGLE WAFER CLEANING AND DRYING.” This U.S. patent, which is assigned to Lam Research Corporation, the assignee of the subject application, is incorporated herein by reference.

The wet cleaning applicator 170 includes controls to control the flow of the wet cleaning chemistry into the third housing chamber 156 so that the wet cleaning chemistry is applied to the surface of the substrate in a controlled manner. In the embodiment where a proximity head is used, the proximity head includes an outlet that is operatively connected to a vacuum port to remove the wet cleaning chemistry and the polymer residue released in the third housing chamber 154 during the cleaning operation so that fresh wet cleaning chemistry may be introduced for a more effective cleaning. The substrate is moved through the third housing chamber 156 and a substantially clean substrate is delivered through the exit port (not shown).

FIG. 2B is an alternate embodiment of the invention wherein a single shower head 160 is used to supply an etchant to the surface of the substrate 100 in the first housing chamber 152 and to supply a dry flash chemistry to the substrate 100 during the short dry flash process. In this embodiment, the shower head 160 is connected to a RF generator through a matching network (not shown) to energize the shower head 160. Likewise, a chuck within the first housing chamber 152 is used to receive the substrate 100 and is energized by a RF generator through a matching network (not shown). In this embodiment, an etchant (supplied from a reservoir) is applied to the surface of the substrate to etch features. A stripping operation follows the etching operation to remove the etchant and a dry flash chemistry is applied to the surface of the substrate in a short flash process so as to substantially remove the polymer residues deposited during the etching and stripping operations. By combining the etching operation with a dry flash operation using a single shower head 160, a substantial reduction in cycle time for cleaning the substrate 100 may be achieved. Additionally, combining the two operations in one chamber prevents other impurities present in ambient air (when moving the substrate 100 from one chamber to another) from adhering to the surface of the substrate or undesired reaction between materials on substrate 100 and ambient air.

In this embodiment, an etch stop layer is deposited over the dielectric film layer, a photoresist (PR) mask is applied, and an etchant is introduced into the first housing chamber 152 through a shower head 160 to define a feature through the dielectric film layer. The etchant is applied to the surface of the substrate in a controlled manner so that features may be efficiently etched. The etchant used for etching features usually include mixtures of fluorocarbons, hydrofluorocarbons, oxygen and nitrogen gases that can leave polymer residues on the dielectric sidewall and bottom of the etched structures. The PR mask and the etch stop layer are stripped in a stripping operation using stripping chemicals introduced through the shower head 160.

During the stripping operation where the PR mask layer and the etch stop layer are stripped, residues from the stripping chemical may also be deposited as polymer residue along the walls and bottom of the feature formed in the low-k dielectric film layer 110 of the substrate 100. In another embodiment, a hard mask layer is used instead of the PR mask layer. In this embodiment, the stripping operation strips the hard mask layer and the etch stop layer.

Upon a successful etching and stripping operations, the substrate is treated with dry flash chemistry using the same shower head 160 in a short flash process so as to remove the polymer residues left behind by the etchant and the stripping chemicals, as illustrated in FIG. 2B. The dry flash chemistry reacts with the polymer residue and releases at least a portion of the polymer residue from the surface of the substrate 100. The released polymer residue along with the dry flash chemistry is promptly removed from the first housing chamber 152 through an outlet operatively connected to a vacuum port. The vacuum port may include an outlet control that controls the amount of various chemistries that can be removed from the first housing chamber 152. The substrate is then transported to a second chamber 156. The supply of etchant and dry flash chemistry may be controlled through an inlet control.

The second chamber 156 includes a wet cleaning applicator 170 that introduces a wet cleaning chemistry into the second chamber 156. The wet cleaning applicator 170 includes controls that control the introduction of the wet cleaning chemistry into the second chamber 156 for effectively cleaning the surface of the substrate 100. In the embodiment illustrated in FIG. 2B, the wet cleaning applicator is a proximity head 170 and the wet cleaning chemistry is applied as a liquid meniscus to the surface of the substrate 100. Since portions of the polymer residue have already been effectively removed from the surface of the substrate by the short flash process, a less complex wet cleaning chemistry may be chosen and applied to the surface of the substrate for a shorter period of time in order to obtain a substantially residue-free substrate surface.

In the embodiments illustrated in FIGS. 2A and 2B, the controls that control the flow of the etchant, the dry flash chemistry and wet cleaning chemistry may each be communicatively connected to a computing system 175 (not shown). A software running on the computing system 175 may be used to adjust one or more parameters of the etchant, dry flash chemistry and the wet cleaning chemistry to ensure controlled application of the etchant, dry flash chemistry and wet cleaning chemistry to the surface of the substrate 100 for effective cleaning. The computing system 175 may be located anywhere so long as the computing system 175 is communicatively linked to the controls that enable controlling the parameters of the dry flash chemistry and the wet cleaning chemistry. Likewise, the RF generators may be connected to the computing system 175 so that energy provided to the shower head 160/165 and the chuck(s) may be controlled for optimal result. The outlet control to the vacuum ports may also be connected to the computing system 175 so that removal of the various chemistries and polymer residues released during cleaning operations may be effectively controlled.

In the embodiments illustrated in FIGS. 2A and 2B, the introduction of the wet cleaning chemistry is not restricted to a proximity head 170 that introduces the wet cleaning chemistry as a liquid meniscus onto the surface of the substrate. Other forms of applying the wet cleaning chemistry to the surface of the substrate may be employed such as a wet chemical dip, a spray nozzle, or a brush box. The dry flash chemistry may use an oxidation process or a reduction process to act on the polymer residue and release the polymer residue from the dielectric walls and bottom of the feature formed through the dielectric film layer. The dry flash chemistry that has shown promising results include low-pressure dry gas such as carbon-dioxide, oxygen, ammonia, nitrogen, hydrogen, carbon monoxide, argon, methane or any combination thereof. The parameters of dry flash chemistry that can be adjusted by the computing system 175 include pressure, flow rate, power and exposure time. The parameters of dry flash chemistry that have shown promising results include pressure between about 5 mTorr to about 40 mTorr with an average pressure of about 20 mTorr, a flow rate between about 50 standard cubic centimeters per minute (sccm) to about 1000 sccm with an average flow rate of about 400 sccm, power between about 50 w to about 1000 w with an average power of about 500 w, time of exposure between about 3 seconds to about 20 seconds with an average time of exposure about 5-10 seconds. As a substantial amount of polymer residue has already been removed from the substrate surface, a less complex wet cleaning chemistry may be chosen to provide optimal cleaning of the polymer residue left behind by the short flash process. The wet cleaning chemistry that has shown promising results in removing the remaining polymer residue includes simple wet cleaning chemistries such as hydrogen fluoride and ammonium fluoride.

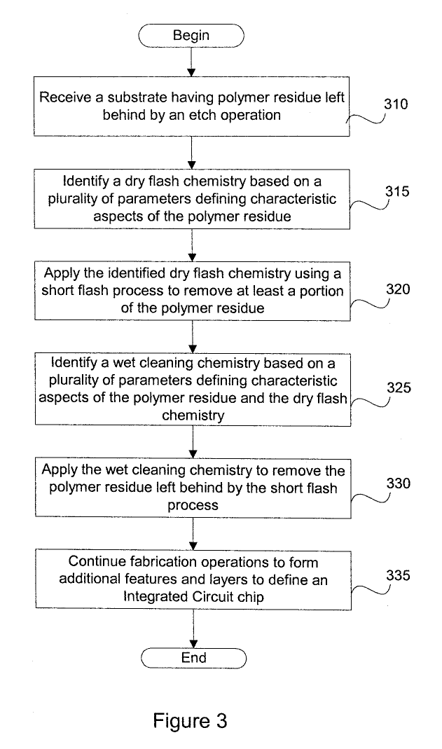

A method for removing post-etch polymer residue from the surface of the substrate will now be described in detail with reference to FIG. 3. The method begins with the operation of receiving a substrate after a post-etch operation, as shown in operation 310. The etchants and stripping chemicals used during etch and strip operations may result in the deposition of polymer residues at the bottom and along the walls of a low-k dielectric film layer where a feature was etched. A dry flash chemistry is identified based on the type of polymer residue deposited on the surface of the substrate 100. The characteristics of the polymer residue are analyzed and the dry flash chemistry is identified based on the analysis, as shown in operation 315. The identified dry flash chemistry is applied to the surface of the substrate using a short flash process, as shown in operation 320. The short flash process enables the dry flash chemistry to effectively act on the polymer residue and remove a substantial portion of the polymer residue deposited along the walls of the dielectric film layer without damaging the dielectric film layer or the enclosed feature.

The dry flash process is immediately followed by a wet cleaning operation. A wet cleaning chemistry is identified by analyzing the characteristics of the polymer residue and the dry flash chemistry defined by one or more of the respective parameters, as shown in operation 325. The identified wet cleaning chemistry is applied to the surface of the substrate 100 in a controlled manner, as shown in operation 330. The wet cleaning chemistry is applied using anyone of a cleaning tool such as proximity head, brush box, wet tank dip, or spray nozzle. The wet cleaning chemistry further aids in the removal of the polymer residue without damaging the features and the surrounding walls of the dielectric film layer. The method continues with operation 335, wherein additional layers and features may be formed over the low-k dielectric film layer to define an integrated circuit chip (IC chip). Some of the additional layers that may be formed include barrier layer, copper film layer deposited to define metallization interconnects and low-k dielectric film layer deposited to separate the features formed during the various fabrication operations, etc. The process may repeat till IC chips are formed on the substrate or some level of fabrication is reached.

Advantages of using both a short flash process and wet cleaning operation include usage of a less complex wet cleaning chemistry, reduction in the cleaning time while producing a substantial polymer free substrate and reduction in cost due to the usage of a less complex wet cleaning chemistry.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method for processing a substrate, comprising:
etching a surface of the substrate using an etching chemistry in a plasma chamber, the etching configured to define one or more features on the surface of the substrate, the one or more features having at least some etch polymer residues as a result of the etching;
terminating the etching with the etching chemistry;
after terminating the etching, applying a dry flash chemistry into the plasma chamber, the plasma chamber then being powered for a period of time of between about 5 seconds and about 10 seconds to perform a dry flash etch, during the dry flash etch, the plasma chamber is set to a low pressure of between about 5 mTorr and about 40 mTorr, the dry flash etch acting to weaken adhesion of the etch polymer residues to the one or more features; and
moving the substrate from the plasma chamber and into a wet clean chamber for fluid cleaning, the fluid cleaning being applied over the etch polymer residues that have weakened adhesion, wherein etch polymer residues are removed during the fluid cleaning.

2. The method of claim 1, wherein the dry flash chemistry is a low-pressure dry gas selected from the group consisting essentially of carbon dioxide, oxygen, ammonia, nitrogen, hydrogen, methane, ethylene, carbon monoxide, argon or combinations thereof.

3. The method of claim 1, wherein the fluid cleaning utilizes chemistries that include hydrogen fluoride, ammonium fluoride, or combinations thereof.

4. The method of claim 1, wherein the etch polymer residues include a carbon containing organic compound.
